(19) United States
(12) Patent Application Publication
(10) Pub. No.: US 2018/0139873 A1
(43) Pub. Date: May 17, 2018

(54) Electromagnetic Wave Absorbing Structures Including Metal-Coated Fabric Layer And Methods Of Manufacturing The Same

(71) Applicant: Korea Advanced Institute of Science and Technology, Daejeon (KR)

(72) Inventors: Chun-Gon Kim, Daejeon (KR); Young-Woo Nam, Daejeon (KR); Jae-Hun Choi, Daejeon (KR)

(73) Assignee: Korea Advanced Institute of Science and Technology, Daejeon (KR)

(21) Appl. No.: 15/809,345

(22) Filed: Nov. 10, 2017

(30) Foreign Application Priority Data
Nov. 11, 2016 (KR) 10-2016-0150304

(51) Int. Cl. H05K 9/00

(52) U.S. Cl. CPC H05K 9/0081

(57) ABSTRACT

An electromagnetic wave absorber includes a metal-coated fabric layer including a metal-coated fiber, and a supporting layer combined with the metal-coated fabric layer. The electromagnetic wave absorber may be easily manufactured and easily adjusted to change an absorbing ability, and may have superior mechanical properties.

### CROSS-REFERENCE TO RELATED APPLICATION

This application claims priority under 35 USC § 119 to Korean Patent Application No. 10-2016-0150304 filed on Nov. 11, 2016 in the Korean Intellectual Property Office (KIPO), the disclosure of which is incorporated by reference herein in its entirety.

### BACKGROUND

1. Field

Exemplary embodiments of the inventive concept relate to an electromagnetic wave absorber. More particularly, exemplary embodiments of the inventive concept relate to an electromagnetic wave absorber and a method of manufacturing the electromagnetic wave absorber.

2. Description of the Related Art

A stealth technology is a technology for reducing or controlling various signals so that weapon systems may not be easily detected by an infrared signal, an acoustic signal, an optical signal and an electronic signal by a radar from an opposite party. Methods for implementing the stealth technology for aircrafts may consider a shaping design, a radar absorbing material (RAM) and a radar absorbing structure (RAS). The shaping design is performed to scatter an electromagnetic wave from a radar in a direction not heading to the radar based on a step of aircraft design. The RAM applies a material capable of absorbing an electromagnetic wave to a surface of an aircraft. The RAS provides a structure capable of supporting a weight as well as absorbing an electromagnetic wave in order to compensate for the shaping design and the RAM, which may be weak at durability. Known configuration as the RAS may include an reinforced fiber, a matrix and nano-particles (filler), which may substantially determine an absorbing ability. A conventional RAS may have various permittivities depending on an amount of the nano-particles. In order to increase the absorbing ability, the RAS need to include a large amount of the nano-particles.

However, a method of dispersing dielectric and magnetic nano-particles is very complicated and may be changed depending on an operator. Thus, the step of dispersing the nano-particles may increase uncertainty in a design step. Furthermore, the nano-particles may increase a viscosity thereby reducing a volume fraction of a fiber to deteriorate mechanical properties. Furthermore, since design freedom may be reduced, manufacturing various absorbers may be difficult.

Korean Patent No. 10-1578474, which is a conventional method, relates to a method of manufacturing a customized radar absorbing structure having variable electromagnetic characteristics using a single composite and a radar absorbing structure thereby, and provides various radar absorbing structures using a prepreg including a nano-material and using variation of electromagnetic characteristics of a composite depending on a molding pressure. However, the above invention also disperses nano-particles in a matrix. Thus, changing a molding pressure for a single composite is not enough to increase freedom of designing electromagnetic characteristics so as to manufacture various radar absorbing structures. Furthermore, it is difficult to control a thickness of the radar absorbing structures in a design step.

### SUMMARY

Exemplary embodiments provide an electromagnetic wave absorber that may be easily manufactured and easily adjusted to change an absorbing ability, and may have superior mechanical properties.

Exemplary embodiments provide a method of manufacturing the above-mentioned electromagnetic wave absorber.

According to an exemplary embodiment, an electromagnetic wave absorber includes a metal-coated fabric layer including a metal-coated fiber, and a supporting layer combined with the metal-coated fabric layer.

In an exemplary embodiment, the metal-coated fiber includes a base fiber and a metal-coating layer formed on a surface of the base fiber by a physical deposition.

In an exemplary embodiment, the supporting layer includes a resin matrix and a reinforcing fiber impregnated in the resin matrix.

In an exemplary embodiment, the resin matrix includes at least one selected from the group consisting of an epoxy resin, a phenol resin, a polyimide resin, an acryl resin and a polyester resin.

In an exemplary embodiment, the reinforcing fiber includes a glass fiber or an aramid fiber.

In an exemplary embodiment, the metal-coating layer includes at least one selected from the group consisting of silver, nickel, cobalt and iron.

In an exemplary embodiment, the base fiber includes a glass fiber or an aramid fiber.

In an exemplary embodiment, the electromagnetic wave absorber is configured to absorb an electromagnetic wave having a wavelength in a range of 8.2 to 12.4 GHz corresponding to X-band.

In an exemplary embodiment, the electromagnetic wave absorber further includes an impedance-adjusting layer combined with the metal-coated fabric layer and including a foam of a polymeric resin.

In an exemplary embodiment, the electromagnetic wave absorber is configured to absorb an electromagnetic wave having a wavelength in a range of 4 to 18 GHz corresponding to C-Ku band.

In an exemplary embodiment, a specific sheet resistance of the metal-coated fabric layer is about 250 ohm/sq to about 350 ohm/sq.

According to an exemplary embodiment, a method for manufacturing an electromagnetic wave absorber is provided. According to the method, a metal is deposited on a base fabric to form a metal-coated fabric including a metal-coated fiber. The metal-coated fabric is combined with a supporting layer.

In an exemplary embodiment, the metal is deposited by a sputtering process.

In an exemplary embodiment, a prepreg sheet including a reinforcing fiber impregnated in a resin matrix is deposited and pressed on the metal-coated fabric layer to combine the metal-coated fabric with the supporting layer.

According to the exemplary embodiments of the present inventive concept, a dielectric loss material or a magnetic loss material are not dispersed in a matrix, and may be provided in a metal-coated fabric layer. Thus, decrease of reliability due to difficulty of dispersing particles in a matrix may be prevented. Furthermore, a volume fraction of a fiber may be increased, and mechanical properties of an electromagnetic wave absorber may be improved by a fabric layer included therein.

Furthermore, electromagnetic characteristics of an electromagnetic wave absorber, such as a magnetic permeability or a permittivity, may be easily controlled or adjusted by changing deposition time of a physical vapor deposition or the like. Thus, electromagnetic wave absorbers capable of absorbing electromagnetic waves of various bands may be provided as desired.

It is to be understood that both the foregoing general description and the following detailed description are exemplary and explanatory and are intended to provide further explanation of the invention as claimed.

### BRIEF DESCRIPTION OF THE DRAWINGS

The above and other features of the inventive concept will become more apparent by describing in detail exemplary embodiments thereof with reference to the accompanying drawings, in which:

FIG. 1 is a cross-sectional view illustrating an electromagnetic wave absorber according to an exemplary embodiment.

FIGS. 2 and 3 are enlarged cross-sectional views illustrating a metal-coated fiber of an electromagnetic wave absorber according to an exemplary embodiment.

FIG. 4 is a cross-sectional view illustrating an electromagnetic wave absorber according to another exemplary embodiment.

FIG. 5 is a graph illustrating (a) a real permittivity and (b) an imaginary permittivity of the electromagnetic wave absorber according to Example 1 in the X-band.

FIG. 6 is a scanning electron microscopy (SEM) picture showing a surface and a cross-section of a silver-coated glass fabric.

FIG. 7 is an energy dispersion spectroscopy (EDS) graph showing a result of analyzing contents of the silver-coated glass fabric and the pristine glass fabric.

FIG. 8 is a graph illustrating an interlaminar shear strength of the silver-coated glass fabric and the pristine glass fabric, which was measured according to ASTM D2344.

FIG. 9 is a graph illustrating a return loss of electromagnetic wave absorbers according to Example 1.

FIG. 10 is a graph illustrating a return loss of electromagnetic wave absorbers according to Example 1, of which a low dielectric layer was additionally attached thereto.

### DETAILED DESCRIPTION

Exemplary embodiments are described more fully hereinafter with reference to the accompanying drawings. The inventive concept may, however, be embodied in many different forms and should not be construed as limited to the exemplary embodiments set forth herein. In the drawings, the sizes and relative sizes of layers and regions may be exaggerated for clarity. It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of exemplary embodiments.

Exemplary embodiments are described herein with reference to cross sectional illustrations that are schematic illustrations of illustratively idealized exemplary embodiments (and intermediate structures) of the inventive concept. As such, variations from the shapes of the illustrations as a result, for example, of manufacturing techniques and/or tolerances, are to be expected. Thus, exemplary embodiments should not be construed as limited to the particular shapes of regions, illustrated herein but are to include deviations in shapes that result, for example, from manufacturing. The regions illustrated in the figures are schematic in nature and their shapes are not intended to illustrate the actual shape of a region of a device and are not intended to limit the scope of the inventive concept.

The terminology used herein is for the purpose of describing particular exemplary embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

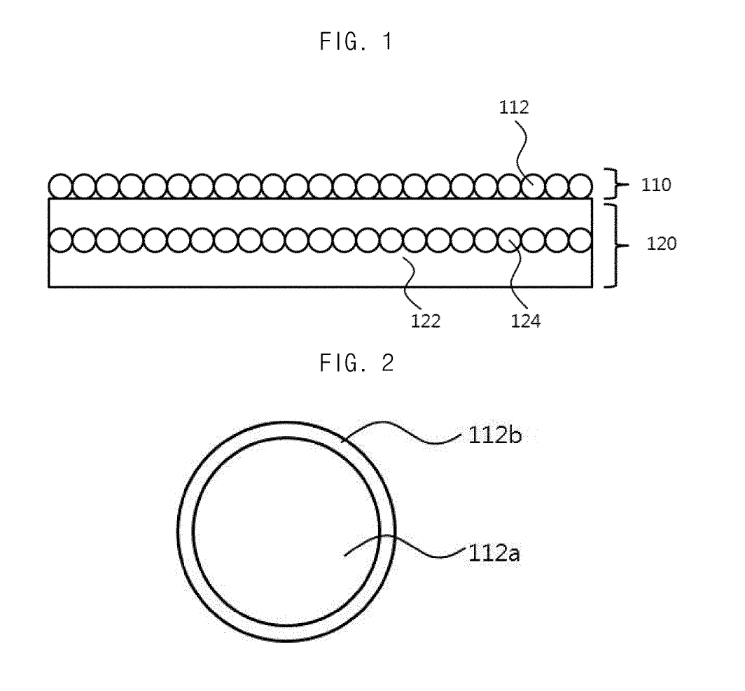

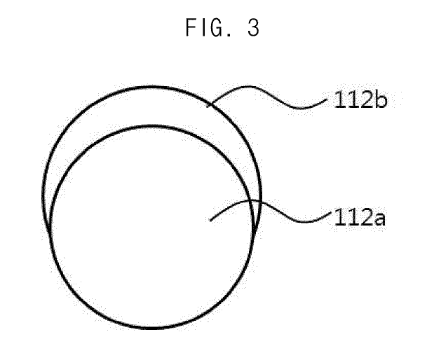

FIG. 1 is a cross-sectional view illustrating an electromagnetic wave absorber according to an exemplary embodiment. FIGS. 2 and 3 are enlarged cross-sectional views illustrating a metal-coated fiber of an electromagnetic wave absorber according to an exemplary embodiment.

Referring to FIG. 1, an electromagnetic wave absorber includes a metal-coated fabric layer 110 and a supporting layer 120. The metal-coated fabric layer 110 includes a metal-coated fiber 112. For example, the metal-coated fabric layer 110 may include metal-coated fibers crossing each other as a weft and a warp. For example, each of the weft and the warp may be a single metal-coated filament, or may include a group or a yarn of metal-coated fibers.

The metal-coated fabric layer 110 may increase a dielectric loss component in the electromagnetic wave absorber.

Referring to FIGS. 1 and 2, the metal-coated fiber 112 may include a base fiber 112a and a metal-coating layer 112b coated on the base fiber 112a.

For example, the base fiber 112a may include a glass fiber, an aramid fiber (Kevlar) or the like.

For example, the metal-coating layer 112b may include silver (Ag). The metal-coated fiber 112 including silver may increase a dielectric loss component in the electromagnetic wave absorber. The dielectric loss component represents ohmic loss due to heat generated by vibration of molecules and free electrons included in a dielectric substance, when an electromagnetic wave is applied thereto. In an exemplary embodiment, the metal-coating layer 112b may include other metals than silver. The metal of the metal-coating layer 112b may be appropriately selected in view of a conductivity or the like. For example, when the conductivity is excessively high or low, it may be difficult to control electromagnetic characteristics of the electromagnetic wave absorber, or an absorbing ability of the electromagnetic wave absorber may be reduced.

A thickness of the metal-coating layer 112b may be adjusted to adjust a magnetic permeability or a permittivity depending on a wavelength of an electromagnetic wave that the electromagnetic wave absorber purposes to absorb.

In another exemplary embodiment, the metal-coating layer 112b may include a ferromagnetic substance such as ferrite, which has molecular dipole. For example, the metal-coating layer 112b may include iron (Fe), cobalt (Co), nickel (Ni) or the like.

For example, the metal-coating layer 112b may be formed by a physical deposition such as a sputtering process to form a continuous layer consisting of a metal, which does not include aggregation of particles combined with each other by a binder or the like. For example, a physical deposition such as a sputtering process may be performed on a base fabric including base fibers to form the metal-coating layer 112b.

As illustrated in FIG. 2, the metal-coating layer 112b may entirely surround the base fiber 112a in a cross-sectional view, however, exemplary embodiments of the present inventive concept are not limited thereto. For example, the metal-coating layer 112b may partially surround the base fiber 112a as illustrated in FIG. 3, for example, when a metal source is provided in one direction. In another exemplary embodiment, the metal-coating layer 112b may have an asymmetric thickness.

For example, a diameter of the base fiber 112a may be 1 to about 50 μm, and a thickness of the metal-coating layer 112b may be 0.1 to about 10 μm. However, exemplary embodiments of the present inventive concept are not limited thereto, and a diameter of the base fiber 112a and a thickness of the metal-coating layer 112b may be adjusted depending on a desired absorbing wavelength or the like.

The supporting layer 120 may support the metal-coated fabric 110 and adjust a permittivity of the electromagnetic wave absorber.

The supporting layer 120 may include a matrix 122 and a reinforcing fiber 124 impregnated in the matrix 122. A ratio of the matrix 122 and the reinforcing fiber 124 may be adjusted to adjust a magnetic permeability or a permittivity depending on a wavelength of an electromagnetic wave that the electromagnetic wave absorber purposes to absorb.

For example, the matrix 122 may include a polymeric resin such as an epoxy resin, a phenol resin, a polyimide resin, an acryl resin, a polyester resin or the like. In an exemplary embodiment, the matrix 122 may include a thermocurable resin such as an epoxy resin.

For example, the reinforcing fiber 124 may include a glass fiber, an aramid fiber (Kevlar), a carbon fiber or the like. In an exemplary embodiment, the reinforcing fiber 124 may include a glass fiber.

A thickness of the electromagnetic wave absorber may be adjusted depending on a wavelength of an electromagnetic wave that the electromagnetic wave absorber purposes to absorb. For example, a thickness of the electromagnetic wave absorber may be about ¼ of a wavelength of an electromagnetic wave to be absorbed. For example, the electromagnetic wave absorber may be designed to absorb an electromagnetic wave having a wavelength in a range of 8.2 to 12.4 GHz corresponding to the X-band.

As explained in the above, a thickness of the electromagnetic wave absorber may be about ¼ of a wavelength of an electromagnetic wave to be absorbed, and a specific sheet resistance of the metal-coated fabric layer 110 may be about 250 ohm/sq to about 350 ohm/sq to increase a dielectric loss component. For example, a specific sheet resistance of the metal-coated fabric layer 110 and a thickness of the electromagnetic wave absorber may be calculated and optimized by a genetic algorithm.

A method for manufacturing an electromagnetic wave absorber according to an exemplary embodiment may be explained more fully hereinafter.

A physical vapor deposition may be performed on a base fabric including a base fiber to form a metal-coated fabric layer 110 including a metal-coated fiber 112.

Thereafter, a supporting layer 120 may be combined with a surface of the metal-coated fabric layer 110. For example, a prepreg sheet including a polymeric resin and a reinforcing fiber 124 may be deposited on the metal-coated fabric layer 110 and then heated and pressed to form the supporting layer 120. For example, as described in Korean Patent No. 10-1578474, which is assigned to the same applicant as the application, a permittivity of the supporting layer 120 may be controlled by adjusting spill of a resin by using a peel ply, a perforated release film, a breather and a vacuum bag film. However, exemplary embodiments of the present inventive concept are not limited thereto, for example, a supporting layer 120 may be combined with the metal-coated fabric layer 110 by an adhesive.

According to an exemplary embodiment, a dielectric loss material or a magnetic loss material are not dispersed in a matrix, and may be provided in a metal-coated fabric layer. Thus, decrease of reliability due to difficulty of dispersing particles in a matrix may be prevented. Furthermore, a volume fraction of a fiber may be increased, and mechanical properties of an electromagnetic wave absorber may be improved by a fabric layer included therein.

Furthermore, electromagnetic characteristics of an electromagnetic wave absorber, such as a magnetic permeability or a permittivity, may be easily controlled or adjusted by changing deposition time of a physical vapor deposition or the like. Thus, electromagnetic wave absorbers capable of absorbing electromagnetic waves of various bands may be provided as desired.

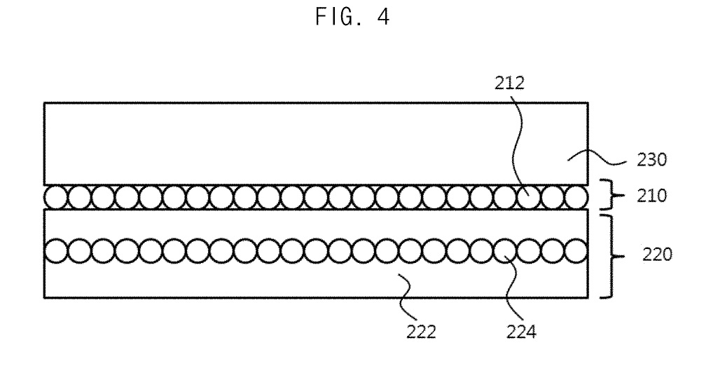

FIG. 4 is a cross-sectional view illustrating an electromagnetic wave absorber according to another exemplary embodiment.

Referring to FIG. 4, an electromagnetic wave absorber includes a metal-coated fabric layer 210, a supporting layer 220 and an impedance-adjusting layer 230. The metal-coated fabric layer 210 includes a metal-coated fiber 212. The supporting layer 210 may include a matrix 222 and a reinforcing fiber 224 impregnated in the matrix 222.

The metal-coated fabric layer 210 and the supporting layer 220 may be substantially same as those previously explained in the above. Thus, any duplicated explanation may be omitted.

The impedance-adjusting layer 230 may be combined with the metal-coated fabric layer 210. Thus, the metal-coated fabric layer 210 may be interposed between the impedance-adjusting layer 230 and the supporting layer 220.

The impedance-adjusting layer 230 may function as a dummy layer to change an impedance of the electromagnetic wave absorber to a matching point. The impedance-adjusting layer 230 may include a dielectric substance having a low permittivity. For example, the impedance-adjusting layer 230 may include a foam including a polymeric resin. For example, the impedance-adjusting layer 230 may include a foam including an acryl cured resin. The polymeric resin may change an absorbing characteristic of the electromagnetic wave absorber with minimizing weight increase.

A thickness of the impedance-adjusting layer 230 may be adjusted depending on a wavelength of an electromagnetic wave to be absorbed. For example, a thickness of the electromagnetic wave absorber may be about ¼ of a wavelength of an electromagnetic wave to be absorbed. For example, a thickness of the electromagnetic wave absorber may be adjusted to absorb an electromagnetic wave having a wavelength in a range of 4 to 18 GHz corresponding to the C-Ku-band.

Hereinafter, effects and configurations of exemplary embodiments of the present inventive concept will be described with reference to specific experimental examples.

### Example 1

A silver was vapor-deposited on a glass fiber fabric (1180, Muhan Composite) by a sputtering apparatus. The glass fiber fabric including a silver layer deposited thereon was disposed on 12 of composite prepreg sheets of a glass fiber and an epoxy resin (GEP 118, Muhan Composite), and an adhesive film (AF126 Scotchweld, 3M) was disposed on the glass fiber fabric. Thereafter, a molding process was performed in an autoclave apparatus using a peel ply, a perforated release film, a breather and a vacuum bag film to manufacture an electromagnetic wave absorber. A copper film tape (PEC) was attached to the electromagnetic wave absorber for an electromagnetic wave absorbing experiment. The deposition time (coating time) of the silver layer of the electromagnetic wave absorber used for the electromagnetic wave absorbing experiment was 6 minutes.

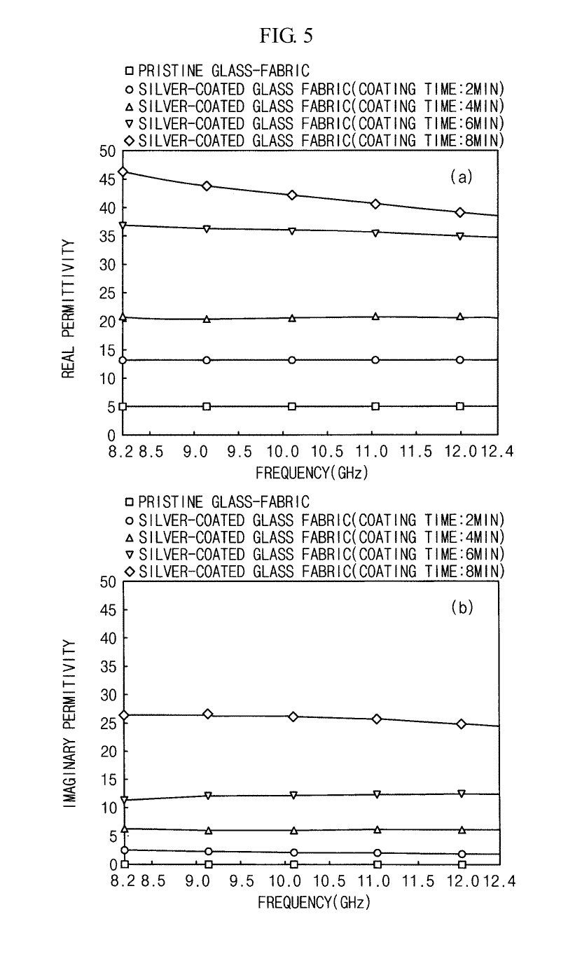

FIG. 5 is a graph illustrating (a) a real permittivity and (b) an imaginary permittivity of the electromagnetic wave absorber according to Example 1 in the X-band.

Referring to FIG. 5, a real permittivity of a pristine glass fabric, which is not conductive, was about 4.3, and an imaginary permittivity of the pristine glass fabric got close to almost 0. However, a real permittivity and an imaginary permittivity increased as a coating time of silver increased. An imaginary permittivity, which is a dielectric loss component, may be induced by dielectric polarization and a free electron. If a viscosity of a medium is too large for dipole to follow field change in the X-band, dielectric relaxation by absorption of a field energy and dielectric loss component may be increased. Accordingly, such dipole effect may increase a complex permittivity.

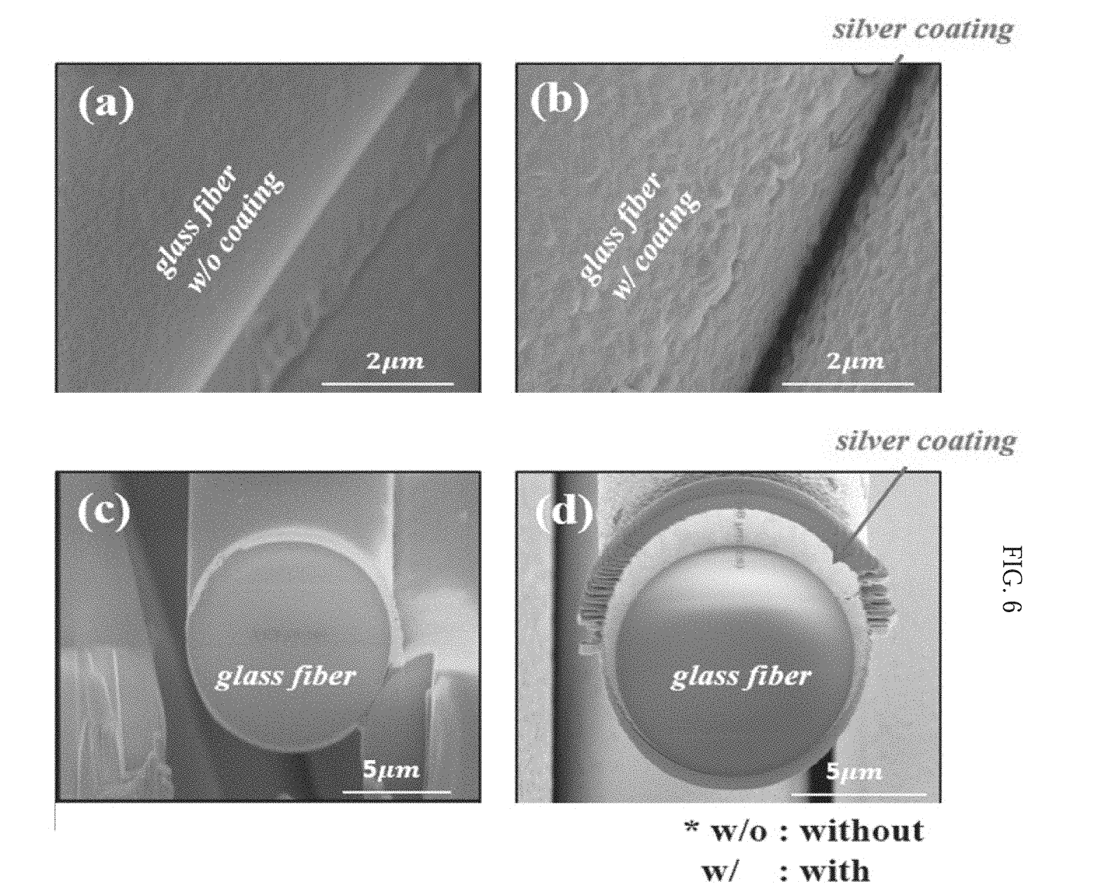

FIG. 6 is a scanning electron microscopy (SEM) picture showing a surface and a cross-section of a silver-coated glass fabric.

Referring to FIG. 6, it can be noted that a silver layer was formed on a glass fiber of the glass fabric after a sputtering process. Furthermore, silver nano-particles were provided along a direction in the sputtering process so that the silver layer was formed asymmetrically.

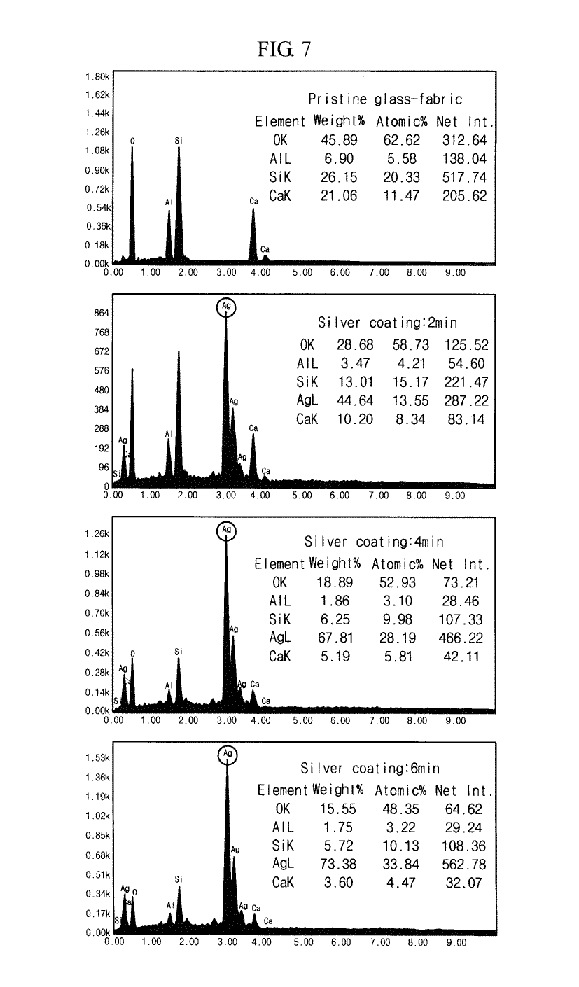

FIG. 7 is an energy dispersion spectroscopy (EDS) graph showing a result of analyzing contents of the silver-coated glass fabric and the pristine glass fabric.

Referring to FIG. 7, it can be noted that a content of silver increased as a coating time of the sputtering process increased.

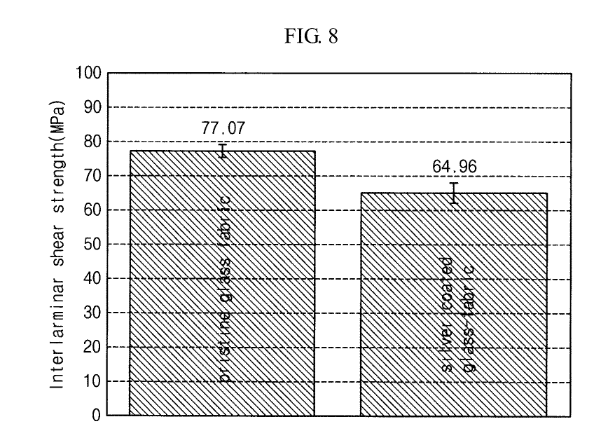

FIG. 8 is a graph illustrating an interlaminar shear strength of the silver-coated glass fabric and the pristine glass fabric, which was measured according to ASTM D2344.

Referring to FIG. 8, it can be noted that the silver-coated glass fabric, which included a silver layer deposited for 6 minutes, according to Example 1 and the pristine glass fabric had an equivalently high inter-laminar shear strength. Thus, it can be noted that the silver-coated glass fabric according to Example 1 may have reliability and structural stability as a composite material for an electromagnetic wave absorber.

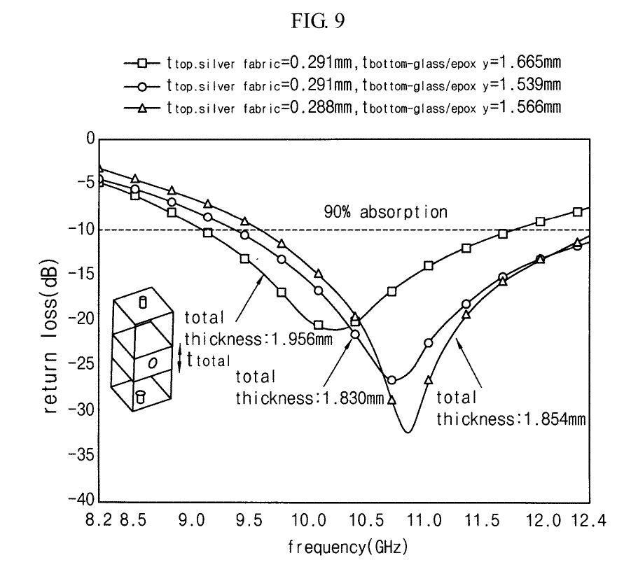

FIG. 9 is a graph illustrating a return loss of electromagnetic wave absorbers according to Example 1. Thicknesses of the electromagnetic wave absorbers were adjusted by changing a pressure of an autoclave process. The coating time of the silver layer of the electromagnetic wave absorbers was 6 minutes (Complex permittivity: 36.271-j12.218). In FIG. 9, “top.silver.fabric” represents a silver-coated glass fabric, and “bottom.glass/epoxy” represents a glass fiber-epoxy supporting layer.

Referring to FIG. 9, while thicknesses of the electromagnetic wave absorbers were less than 2 mm, the electromagnetic wave absorbers had an absorbing ability of larger than −10 db with a coverage of about 2.34 to about 2.78 GHz in a range of about 8.2 to about 12.4 GHz corresponding to the X-band.

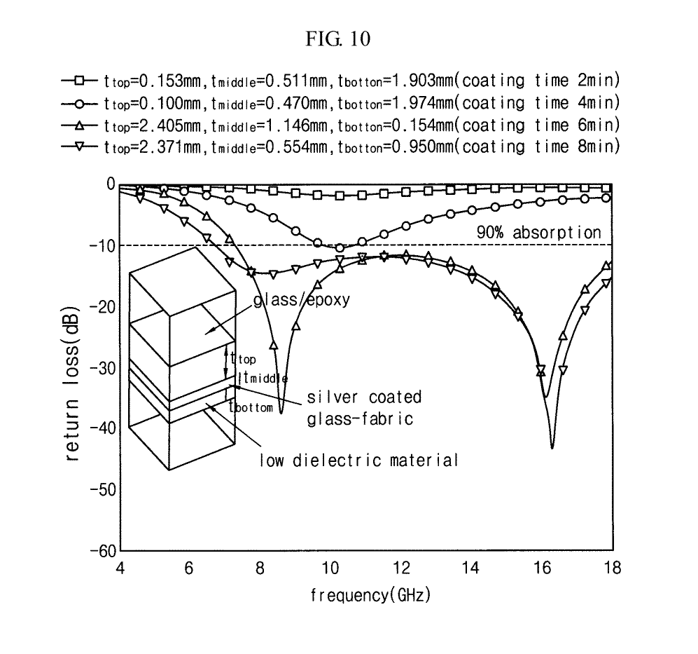

FIG. 10 is a graph illustrating a return loss of electromagnetic wave absorbers according to Example 1, of which a low dielectric layer was additionally attached thereto. An acrylic foam was provided as the low dielectric layer. In FIG. 10, “top” represents a glass fiber-epoxy supporting layer silver-coated glass fabric, “middle” represents a silver-coated glass fabric (Complex permittivity: 36.271-j12.218), and “bottom” represents a low dielectric layer.

Referring to FIG. 10, it can be noted that the electromagnetic wave absorbers can have an absorbing ability of larger than −10 db in other ranges than the X-band, for example, between the C-band and the X-band, or between the X-band and the Ku-band. Thus, it can be noted that the electromagnetic wave absorbers can be used for wideband electromagnetic wave absorbers.

Electromagnetic wave absorbers according to exemplary embodiment may be used for a cutting edge mechanical field, to which a stealth technology may be applied, such as an aerospace field.

The foregoing is illustrative and is not to be construed as limiting thereof. Although a few exemplary embodiments have been described, those skilled in the art will readily appreciate that many modifications are possible in the exemplary embodiments without materially departing from the novel teachings, aspects, and advantages of the invention. Accordingly, all such modifications are intended to be included within the scope of this

[symbol]

What is claimed is:

1. An electromagnetic wave absorber comprising:
a metal-coated fabric layer including a metal-coated fiber; and
a supporting layer combined with the metal-coated fabric layer.

2. The electromagnetic wave absorber of claim 1, wherein the metal-coated fiber includes a base fiber and a metal-coating layer formed on a surface of the base fiber by a physical deposition.

3. The electromagnetic wave absorber of claim 2, wherein the supporting layer includes a resin matrix and a reinforcing fiber impregnated in the resin matrix.

4. The electromagnetic wave absorber of claim 3, wherein the resin matrix includes at least one selected from the group consisting of an epoxy resin, a phenol resin, a polyimide resin, an acryl resin and a polyester resin.

5. The electromagnetic wave absorber of claim 3, wherein the reinforcing fiber includes a glass fiber or an aramid fiber.

6. The electromagnetic wave absorber of claim 2, wherein the metal-coating layer includes at least one selected from the group consisting of silver, nickel, cobalt and iron.

7. The electromagnetic wave absorber of claim 2, wherein the base fiber includes a glass fiber or an aramid fiber.

8. The electromagnetic wave absorber of claim 2, wherein the electromagnetic wave absorber is configured to absorb an electromagnetic wave having a wavelength in a range of 8.2 to 12.4 GHz corresponding to X-band.

9. The electromagnetic wave absorber of claim 1, further comprising:
an impedance-adjusting layer combined with the metal-coated fabric layer and including a foam of a polymeric resin.

10. The electromagnetic wave absorber of claim 9, wherein the electromagnetic wave absorber is configured to absorb an electromagnetic wave having a wavelength in a range of 4 to 18 GHz corresponding to C-Ku band.

11. The electromagnetic wave absorber of claim 1, wherein a specific sheet resistance of the metal-coated fabric layer is about 250 ohm/sq to about 350 ohm/sq.

12. A method of manufacturing an electromagnetic wave absorber, the method comprising:
physically depositing a metal on a base fabric to form a metal-coated fabric including a metal-coated fiber; and
combining the metal-coated fabric with a supporting layer.

13. The method of claim 12, wherein a metal-coating layer of the metal-coated fiber includes at least one selected from the group consisting of silver, nickel, cobalt and iron, wherein the base fabric includes a glass fiber or an aramid fiber.

14. The method of claim 12, wherein the metal is deposited by a sputtering process.

15. The method of claim 12, wherein combining the metal-coated fabric with the supporting layer comprises:
depositing and pressing a prepreg sheet including a reinforcing fiber impregnated in a resin matrix on the metal-coated fabric.
